(19) United States
(12) Patent Application Publication
(10) Pub. No.: US 2012/0012454 A1
(43) Pub. Date: Jan. 19, 2012

(54) FABRICATION METHOD OF CRYSTALLIZED TRANSPARENT CONDUCTING OXIDES ON SELF-ASSEMBLED ORGANIC LAYER MODIFIED SUBSTRATE

(75) Inventors: Yian Tai, Taipei City (TW); Hsuan-chun Chang, Taipei City (TW)

(73) Assignee: National Taiwan University of Science and Technology, Taipei City (TW)

(21) Appl. No.: 12/884,173

(22) Filed: Sep. 16, 2010

(30) Foreign Application Priority Data
Jul. 15, 2010 (TW) 099123363

(51) Int. Cl. C23C 14/34; C23C 14/08

(52) U.S. Cl. 204/192.1

(57) ABSTRACT

A fabrication method of crystallized transparent conducting oxides (TCOs) on a self-assembled organic layer modified substrate is provided and said method includes steps of: providing a substrate having a surface; processing the surface of the substrate by an organic molecular solution, so as to form a self-assembled organic layer on the surface of the substrate; and forming a transparent conducting oxide (TCO) layer on the self-assembled organic layer at a lower temperature below 300° C. The self-assembled organic layer can be used to modify the surface of the substrate to form a highly crystallized TCO layer thereon.

### CLAIM OF PRIORITY

This application claim priority to Taiwanese Patent Application No. 099123363 filed on Jul. 15, 2010.

### FIELD OF THE INVENTION

The present invention relates to a fabrication method of crystallized transparent conducting oxides (TCOs) on a self-assembled organic layer modified substrate, and more particularly to a fabrication method of smoothly forming a highly crystallized TCO layer on a modified surface of a substrate modified by a self-assembled organic layer at a relatively lower temperature.

### BACKGROUND OF THE INVENTION

Tin-doped indium oxide (ITO) is the most commonly used transparent conducting oxide (TCO) of various optical and photoelectric devices. For example, ITO can be used as electrodes, resistor furnaces, anti-reflection coatings, heat reflectors, electromagnetic shielding coatings, anti-static coatings and etc., and applied to various technological field including solar cells, gauges, liquid crystal displays (or flat panel displays), organic light emitting diodes, optical detectors. A thin film of high quality ITO must provide high conductivity and high optical transmittance, wherein the foregoing quality can be carried out by a highly crystallized ITO film.

To achieve the above object, various methods are continuously developed to fabricate the ITO film, wherein a high quality ITO material can be formed when the temperature is raised up to about 220° C. However, it needs to consume a great amount of electric power to raise the temperature up to 220° C., and thus the manufacture cost of material will be considerably increased. Furthermore, the high temperature condition is not suitable to many new developed devices recently. Because substrates used by these new devices are generally made of organic macromolecular material, the substrates have heat sensitivity and can not bear high temperature.

To avoid the high temperature condition, a plasma sputtering technology is developed to execute a deposition process at a relatively lower temperature. Thus, the ITO film can be deposited on more types of substrates, especially applied to flexible substrates. However, a disadvantage of the low-temperature deposition process is that: it only can obtain an amorphous ITO material which only can provide high resistance value, limited electric property or other physical/chemical performances.

As a result, it is necessary to provide an improved fabrication method of crystallized transparent conducting oxides on a self-assembled organic layer modified substrate to solve the problems existing in the conventional technologies, as described above.

### SUMMARY OF THE INVENTION

A primary object of the present invention is to provide a fabrication method of crystallized transparent conducting oxides (TCOs) on a self-assembled organic layer modified substrate, wherein the fabrication method firstly provides a substrate having a surface processed to form a self-assembled organic layer thereon for modifying the surface of the substrate, and then forms a highly crystallized transparent conducting oxide (TCO) layer (such as ITO film) on the self-assembled organic layer (i.e. the modified surface) by a low temperature process (such as by a lower power RF plasma sputtering technology at a relatively lower temperature). The self-assembled organic layer can be used to change the physical properties (such as surface energy) of the surface of the substrate and enhance the chemical reactivity thereof, so that it is advantageous to precisely control the surface properties of the surface of the substrate, and form a TCO layer with various excellent physical/chemical properties including crystallinity property, conductivity and optical transmittance on the surface of the substrate.

A secondary object of the present invention is to provide a fabrication method of crystallized transparent conducting oxides (TCOs) on a self-assembled organic layer modified substrate, wherein the fabrication method uses the low temperature process (such as by a lower power RF plasma sputtering technology at a relatively lower temperature) to form the TCO layer on the self-assembled organic layer, so that it can be suitably applied to flexible substrates of organic macromolecular material to form a highly crystallized TCO layer thereon. Thus, it is advantageous to widen the application field of the process and the selectivity of types of substrates and to relatively lower the power consumption during the process.

To achieve the above object, the present invention provides a fabrication method of crystallized transparent conducting oxides on a self-assembled organic layer modified substrate, wherein the fabrication method comprises the following steps of: providing a substrate having a surface; processing the surface of the substrate by an organic molecular solution, so as to form a self-assembled organic layer on the surface of the substrate; and forming a transparent conducting oxide (TCO) layer on the self-assembled organic layer at a temperature lower than 300° C.

In one embodiment of the present invention, the substrate is a rigid substrate, and the rigid substrate is selected from a glass substrate, a silicon substrate, a GaN substrate, a GaAs substrate, a sapphire substrate or other oxide substrates (such as silica substrate or alumina substrate).

In one embodiment of the present invention, the substrate is a flexible substrate, and the flexible substrate is selected from polyethylene terephthalate (PET) substrate, polyimide (PI, Kapton) substrate, polymethyl methacrylate (PMMA) substrate, polycarbonate (PC) substrate, Nylon 66 substrate or polypropylene (PP) substrate.

In one embodiment of the present invention, each of organic molecules in the organic molecular solution (and the self-assembled organic layer) has a head group, a carbon chain skeleton and a terminal group, wherein the head group is connected to the surface of the substrate, the carbon chain skeleton is connected between the head group and the terminal group, and the terminal group is connected to the TCO layer.

In one embodiment of the present invention, the head group of the organic molecule is selected from —COOH, —SH, —PO(OH)₂, —SiCl₃, —Si(OR)₃, alkenyl group or alkynyl group, wherein R is H or Cₙ, and n is a positive integer selected from 1 to 5.

In one embodiment of the present invention, the carbon chain skeleton of the organic molecule is selected from a straight chain, a branched chain or a ring carbon chain of C₃ to C₁₈.

In one embodiment of the present invention, the terminal group of the organic molecule is selected from —SH, —NH₂, —CH₃, —CF₃, —NO₂, —CN or —COOH.

In one embodiment of the present invention, the organic molecule is selected from 3-mercaptopropyltriethoxysilane (SAM-SH), 3-aminopropyltriethoxysilane (SAM-NH₂) or n-propyltriethoxysilane (SAM-CH₃).

In one embodiment of the present invention, a solvent of the organic molecular solution is selected from alkane or aqueous solvent.

In one embodiment of the present invention, after processing the surface of the substrate by the organic molecular solution, further comprising steps of: separating the surface of the substrate from the organic molecular solution, and drying the surface of the substrate under an environment of an anti-oxidation inert gas, wherein the inert gas can be preferably nitrogen.

In one embodiment of the present invention, the self-assembled organic layer is a self-assembled monolayer (SAM) of organic molecules.

In one embodiment of the present invention, the thickness of the self-assembled organic layer is ranged between 0.5 nm and 3 nm.

In one embodiment of the present invention, material of the TCO layer is selected from tin-doped indium oxide (ITO) or Al-doped zinc oxide (AZO).

In one embodiment of the present invention, in the step of forming the TCO layer, using a RF plasma sputtering technology to form the TCO layer on the self-assembled organic layer.

In one embodiment of the present invention, the RF plasma sputtering technology is carried out at room temperature.

### DESCRIPTION OF THE DRAWINGS

FIG. 1A is a schematic view of a step for providing a substrate of a fabrication method of crystallized transparent conducting oxides on self-assembled organic layer modified substrate according to a preferred embodiment of the present invention;

FIG. 1B is a schematic view of a step for modifying the surface of the substrate by an organic molecular solution of a fabrication method of crystallized transparent conducting oxides on self-assembled organic layer modified substrate according to a preferred embodiment of the present invention;

FIG. 1C is a schematic view of a step for forming a self-assembled organic layer on the surface of the substrate of a fabrication method of crystallized transparent conducting oxides on self-assembled organic layer modified substrate according to a preferred embodiment of the present invention;

FIG. 1D is a schematic view of a step for forming a transparent conducting oxide (TCO) layer of a fabrication method of crystallized transparent conducting oxides on self-assembled organic layer modified substrate according to a preferred embodiment of the present invention;

FIG. 2A is an X-ray diffraction pattern of a traditional substrate only having a TCO layer;

FIG. 2B is an electron microscopy photograph of the TCO layer directly connected to the traditional substrate;

FIG. 3A is an X-ray diffraction pattern of a substrate having a self-assembled organic layer and a TCO layer according to the preferred embodiment of the present invention; and

FIG. 3B is an electron microscopy photograph of the TCO layer connected to the self-assembled organic layer on the surface of the substrate according to the preferred embodiment of the present invention.

### DETAILED DESCRIPTION OF THE PREFERRED EMBODIMENTS

The structure and the technical means adopted by the present invention to achieve the above and other objects can be best understood by referring to the following detailed description of the preferred embodiments and the accompanying drawings.

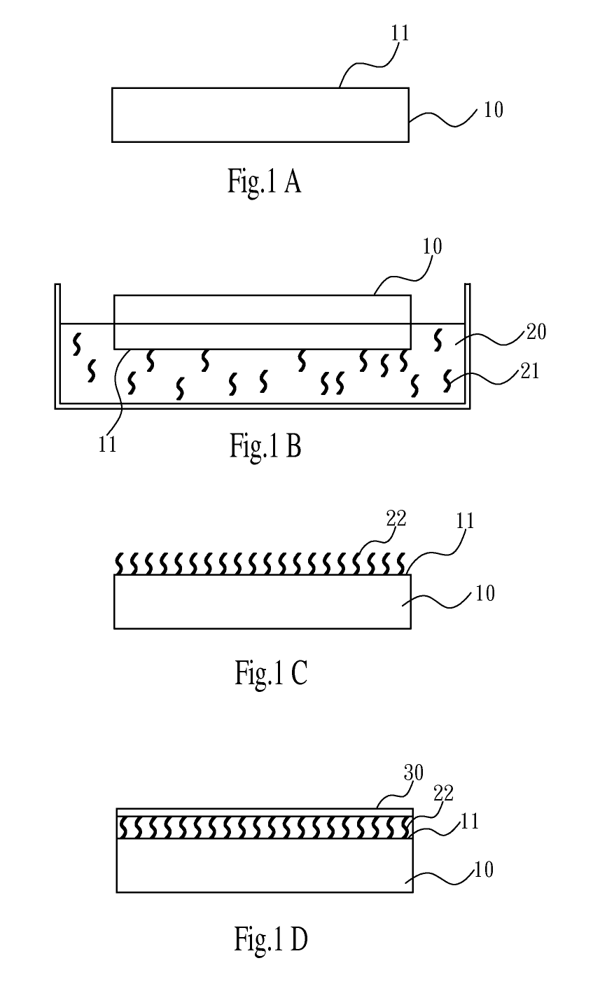

Referring now to FIGS. 1A to 1D, a fabrication method of crystallized transparent conducting oxides on a self-assembled organic layer modified substrate according to a preferred embodiment of the present invention is illustrated. As shown, the fabrication method comprises the following steps of: providing a substrate 10 having a surface 11; processing the surface 11 of the substrate 10 by an organic molecular solution 20, so as to form a self-assembled organic layer 22 on the surface 11 of the substrate 10; and forming a transparent conducting oxide (TCO) layer 30 on the self-assembled organic layer 22 at a temperature lower than 300° C. The present invention will be described more detailed about technological features including processing procedures and fabrication conditions of each step hereinafter.

Referring to FIG. 1A, the fabrication method of crystallized transparent conducting oxides on the self-assembled organic layer modified substrate according to a preferred embodiment of the present invention is firstly to provide a substrate 10 having a surface 11. In the step, the substrate 10 can be a rigid substrate or a flexible substrate, wherein the rigid substrate is preferably selected from a glass substrate, a silicon substrate, a GaN substrate, a GaAs substrate, a sapphire substrate or other oxide substrates (such as silica substrate or alumina substrate), while the flexible substrate is selected from polyethylene terephthalate (PET) substrate, polyimide (PI, Kapton) substrate, polymethyl methacrylate (PMMA) substrate, polycarbonate (PC) substrate, Nylon 66 substrate or polypropylene (PP) substrate. However, the substrate 10 can be other rigid substrate or flexible substrate. One side of the substrate 10 has a surface 11 which is exposed and ready to be processed, while the other side of the substrate 10 has another surface which may be exposed, stacked with other stacked layers, or protected by a temporary protection layer. Before executing the next step, the surface 11 can be washed by suitable solutions in advance. For example, solvents such as deionized water, acetone and 2-propanol can be used in turn for washing. If necessary, ultrasonic vibration means can be used to enhance the washing efficiency.

Referring to FIGS. 1B and 1C, the fabrication method of crystallized transparent conducting oxides on the self-assembled organic layer modified substrate according to a preferred embodiment of the present invention is then to process the surface 11 of the substrate 10 by an organic molecular solution 20, so as to form a self-assembled organic layer 22 on the surface 11 of the substrate 10. In the step, the present invention firstly immerses the surface 11 of the substrate 10 into an organic molecular solution 20, so that the surface 11 can be in contact with organic molecules 21 contained in the organic molecular solution 20 for modification. Then, the surface 11 of the substrate 10 is separated from the organic molecular solution 20, and the surface 11 of the substrate 10 is dried, in order to form a self-assembled organic layer 22 on the surface 11 of the substrate 10. In the embodiment, the solvent of the organic molecular solution 20 can be selected from alkanes, alcohols or aqueous solvent, such as decane. Meanwhile, each of the organic molecules 21 in the organic molecular solution 20 has a head group, a carbon chain skeleton and a terminal group, wherein the head group is connected to the surface 11 of the substrate 10, the carbon chain skeleton is connected between the head group and the terminal group, and the terminal group is connected to the TCO layer 30 described hereinafter. The head group of the organic molecule 21 is selected from —COOH, —SH, —PO(OH)₂, —SiCl₃, —Si(OR)₃, alkenyl group or alkynyl group, wherein R is H or Cₙ, and n is a positive integer selected from 1 to 5; the carbon chain skeleton of the organic molecule 21 is selected from a straight chain, a branched chain or a ring carbon chain of C₃ to C₁₈; and the terminal group of the organic molecule 21 is selected from —SH, —NH₂, —CH₃, —CF₃, —NO₂, —CN or —COOH. For example, in the present invention, the organic molecule 21 of the organic molecular solution 20 is selected from 3-mercaptopropyltriethoxysilane (SAM-SH), 3-aminopropyltriethoxysilane (SAM-NH₂) or n-propyltriethoxysilane (SAM-CH₃), each of which can be solved in the solvent of decane according to a ratio of molar concentration about 0.2 mM. During preparing the solution, ultrasonic vibration can be used to assist to evenly mix the organic molecule 21 in the solvent. In the embodiment, the organic molecule 21 is selected from 3-mercaptopropyltriethoxysilane (SAM-SH) which has a terminal group of —SH.

After the surface 11 of the substrate 10 is in contact with the organic molecule 21 contained in the organic molecular solution 20, the head groups of a plurality of the organic molecules 21 will arrange side by side (i.e. adjacent to each other) and connect to the surface 11 of the substrate 10, so as to carry out the purpose of modifying the surface 11. Generally, the self-assembled organic layer 22 formed during modifying is a self-assembled monolayer (SAM) which is constructed because a plurality of the organic molecules 21 are arranged on the surface 11 along the same direction and with a thickness of mono-molecule. All of the head groups of the organic molecules 21 face and connect to the surface 11, while all of the terminal groups of the organic molecules 21 face outward for connecting to the TCO layer 30 in the next step. As shown in FIG. 1C, after processing the surface 11 of the substrate 10 by the organic molecular solution 20, the surface 11 of the substrate 10 is taken and separated from the organic molecular solution 20, and wash the self-assembled organic layer 22 on the surface 11 of the substrate 10 by suitable solvents (such as decane). Meanwhile, an anti-oxidation inert gas (such as nitrogen) is used to blow the self-assembled organic layer 22 for air drying; or standing in an environment of inert gas for drying, wherein the dry time is about ranged between tens of minutes and several hours according to the types of organic molecules 21. The function of the inert gas is used to prevent the self-assembled organic layer 22 from being oxidized to affect the physical/chemical properties thereof before forming stable status. Finally, according the types of organic molecules 21, the thickness of the self-assembled organic layer 22 is substantially ranged between 0.5 nm and 3 nm.

Referring to FIG. 10, the fabrication method of crystallized transparent conducting oxides on the self-assembled organic layer modified substrate according to a preferred embodiment of the present invention is then to form a transparent conducting oxide (TCO) layer 30 on the self-assembled organic layer 22 at a temperature lower than 300° C. In the step, the present invention preferably uses a RF plasma sputtering technology to form the TCO layer 30 on the self-assembled organic layer 22. The RF plasma sputtering technology is advantageous to form the TCO layer 30 on the self-assembled organic layer 22 carry out at a temperature lower than 300° C., wherein the sputtering temperature is preferably a temperature lower than 250° C., especially a temperature lower than 200° C., such as 25° C. (i.e. room temperature, RT). Furthermore, the material of the TCO layer 30 can be selected from tin-doped indium oxide (ITO) or Al-doped zinc oxide (AZO). In the embodiment, the TCO layer 30 is selected from ITO film. When executing the RF plasma sputtering technology, the target material thereof comprises 90 wt % of In₂O₃ and 10 wt % of SnO₂; the plasma power is 10 W; the pressure in the deposition chamber thereof is small than 5×10⁻⁷ torr. In necessary, it can suitably heat to enhance the crystallinity property of the TCO layer 30. In the embodiment, the RF plasma sputtering technology is executed in an environment of room temperature (RT) about 25° C. After sputtering about 15 minutes, the TCO layer 30 with the thickness of 150 nm can be formed on the self-assembled organic layer 22.

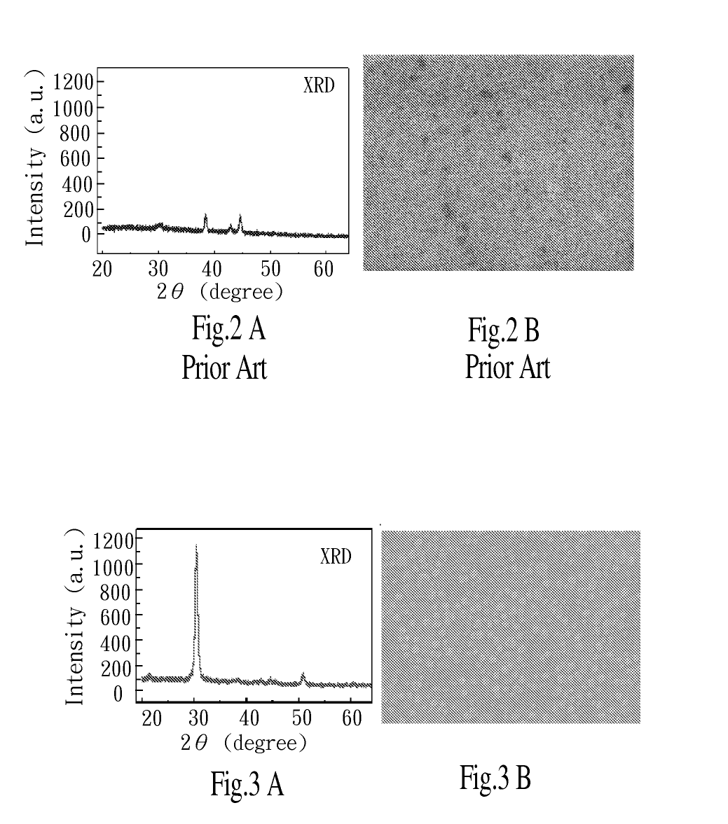

Referring to FIG. 2A, an X-ray diffraction pattern of a traditional substrate only having a TCO layer is illustrated, wherein the traditional substrate has no the self-assembled organic layer 22, so that the X-ray diffraction pattern can not detect any peak value of crystal plane of the TCO layer, and it indicates that the TCO layer is formed on the surface of the substrate in an amorphous form. Referring to FIG. 2B, an electron microscopy photograph of the TCO layer directly connected to the traditional substrate is illustrated, wherein it also can apparently show that the traditional TCO layer is formed on the surface of the substrate in an amorphous form.

In comparison, referring to FIG. 3A, an X-ray diffraction pattern of a substrate having a self-assembled organic layer and a TCO layer according to the preferred embodiment of the present invention is illustrated, wherein the surface 11 of the substrate 10 has the self-assembled organic layer 22, so that the X-ray diffraction pattern can apparently detect two peak values (220) and (440) of crystal plane of the TCO layer 30, both of which indicate that the TCO layer 30 is surely formed on the surface 11 of the substrate 10 in a highly crystallized form. Referring to FIG. 3B, an electron microscopy photograph of the TCO layer connected to the self-assembled organic layer on the surface of the substrate according to the preferred embodiment of the present invention is illustrated, wherein it also can apparently show that the TCO layer 30 is formed on the self-assembled organic layer 22 (i.e. modified surface) on the surface 11 of the substrate 10 in a highly crystallized form. Thus, the present invention can use the self-assembled organic layer 22 to modify the surface 11 of the substrate 10 for surely increasing the crystallinity of the TCO layer 30.

As described above, in comparison with the traditional high temperature process for fabricating the ITO thin film which is not suitably applied to the flexible substrate and will consume a great amount of electric power and the traditional plasma sputtering technology which can be carried out at a lower temperature but only can obtain amorphous ITO thin film, the fabrication method of the present invention as shown in FIGS. 1A to 1D firstly provides a substrate 10 having a surface 11 processed to form a self-assembled organic layer 22 thereon for modifying the surface 11 of the substrate 10, and then forms a highly crystallized transparent conducting oxide (TCO) layer (such as ITO film) on the self-assembled organic layer 22 (i.e. the modified surface) by a low temperature process (such as by a lower power RF plasma sputtering technology at a relatively lower temperature). The self-assembled organic layer 22 can be used to change the physical properties (such as surface energy) of the surface 11 of the substrate 10, and enhance the chemical reactivity thereof, so that the hydrophobic property of the surface 11 is converted into the hydrophilic property (or the hydrophilic property is converted into the hydrophobic property). Meanwhile, the self-assembled organic layer 22 can enhance the chemical reactivity of the surface 11 of the substrate 10. Thus, it is advantageous to precisely control the surface properties of the surface 11 of the substrate 10, and form a TCO layer 30 with various excellent physical/chemical properties including crystallinity property, conductivity and optical transmittance on the surface 11 of the substrate 10. Furthermore, the fabrication method of the present invention uses the low temperature process (such as by a lower power RF plasma sputtering technology at a relatively lower temperature) to form the TCO layer 30 on the self-assembled organic layer 22, so that it can be suitably applied to flexible substrates of organic macromolecular material to form a highly crystallized TCO layer 30 thereon. Thus, it is advantageous to widen the application field of the process and the selectivity of types of substrates and to relatively lower the power consumption during the process.

The present invention has been described with a preferred embodiment thereof and it is understood that many changes and modifications to the described embodiment can be carried out without departing from the scope and the spirit of the invention that is intended to be limited only by the appended claims.

1. A fabrication method of crystallized transparent conducting oxides on a self-assembled organic layer modified substrate, comprising steps of:
providing a substrate having a surface;
processing the surface of the substrate by an organic molecular solution, so as to form a self-assembled organic layer on the surface of the substrate; and
forming a transparent conducting oxide (TCO) layer on the self-assembled organic layer at a temperature lower than 300° C.

2. The fabrication method of crystallized transparent conducting oxides on a self-assembled organic layer modified substrate according to claim 1, wherein the substrate is a rigid substrate, and the rigid substrate is selected from a glass substrate, a silicon substrate, a GaN substrate, a GaAs substrate, a sapphire substrate or an oxide substrate.

3. The fabrication method of crystallized transparent conducting oxides on a self-assembled organic layer modified substrate according to claim 1, wherein the substrate is a flexible substrate, and the flexible substrate is selected from polyethylene terephthalate substrate, polyimide substrate, polymethyl methacrylate substrate, polycarbonate substrate, Nylon 66 substrate or polypropylene substrate.

4. The fabrication method of crystallized transparent conducting oxides on a self-assembled organic layer modified substrate according to claim 1, wherein each of organic molecules in the organic molecular solution and the self-assembled organic layer has a head group, a carbon chain skeleton and a terminal group, wherein the head group is connected to the surface of the substrate, the carbon chain skeleton is connected between the head group and the terminal group, and the terminal group is connected to the TCO layer.

5. The fabrication method of crystallized transparent conducting oxides on a self-assembled organic layer modified substrate according to claim 4, wherein the head group of the organic molecule is selected from —COOH, —SH, —PO(OH)₂, —SiCl₃, —Si(OR)₃, alkenyl group or alkynyl group, wherein R is H or Cₙ, and n is a positive integer selected from 1 to 5.

6. The fabrication method of crystallized transparent conducting oxides on a self-assembled organic layer modified substrate according to claim 4, wherein the carbon chain skeleton of the organic molecule is selected from a straight chain, a branched chain or a ring carbon chain of C₃ to C₁₈.

7. The fabrication method of crystallized transparent conducting oxides on a self-assembled organic layer modified substrate according to claim 4, wherein the terminal group of the organic molecule is selected from —SH, —NH₂, —CH₃, —CF₃, —NO₂, —CN or —COOH.

8. The fabrication method of crystallized transparent conducting oxides on a self-assembled organic layer modified substrate according to claim 4, wherein the organic molecule is selected from 3-mercaptopropyltriethoxysilane, 3-aminopropyltriethoxysilane or n-propyltriethoxysilane.

9. The fabrication method of crystallized transparent conducting oxides on a self-assembled organic layer modified substrate according to claim 1, wherein a solvent of the organic molecular solution is selected from alkane or aqueous solvent.

10. The fabrication method of crystallized transparent conducting oxides on a self-assembled organic layer modified substrate according to claim 1, wherein after processing the surface of the substrate by the organic molecular solution, further comprising steps of: separating the surface of the substrate from the organic molecular solution, and drying the surface of the substrate under an environment of an anti-oxidation inert gas.

11. The fabrication method of crystallized transparent conducting oxides on a self-assembled organic layer modified substrate according to claim 1, wherein the self-assembled organic layer is a self-assembled monolayer of organic molecules.

12. The fabrication method of crystallized transparent conducting oxides on a self-assembled organic layer modified substrate according to claim 11, wherein the thickness of the self-assembled organic layer is ranged between 0.5 nm and 3 nm.

13. The fabrication method of crystallized transparent conducting oxides on a self-assembled organic layer modified substrate according to claim 1, wherein the thickness of the self-assembled organic layer is ranged between 0.5 nm and 3 nm.

14. The fabrication method of crystallized transparent conducting oxides on a self-assembled organic layer modified substrate according to claim 1, wherein material of the TCO layer is selected from tin-doped indium oxide or Al-doped zinc oxide.

15. The fabrication method of crystallized transparent conducting oxides on a self-assembled organic layer modified substrate according to claim 1, wherein in the step of forming the TCO layer, using a RF plasma sputtering technology to form the TCO layer on the self-assembled organic layer.

16. The fabrication method of crystallized transparent conducting oxides on a self-assembled organic layer modified substrate according to claim 15, wherein the RF plasma sputtering technology is carried out at room temperature.
